(19) United States
(12) Patent Application Publication
(10) Pub. No.: US 2026/0190782 A1
(43) Pub. Date: Jul. 2, 2026

(54) DISPLAY DEVICE

(71) Applicant: LG Display Co., Ltd., Seoul (KR)

(72) Inventors: Jae-Ho SIM, Paju-si (KR); Je-Hyung PARK, Paju-si (KR)

(73) Assignee: LG Display Co., Ltd., Seoul (KR)

(21) Appl. No.: 19/395,916

(22) Filed: Nov. 20, 2025

(30) Foreign Application Priority Data
Dec. 30, 2024 (KR) 10-2024-0200603

(51) Int. Cl. H10K 59/80; H10H 29/01; H10H 29/853; H10K 59/12; H10K 71/00

(52) U.S. Cl. CPC H10K 59/873; H10H 29/012; H10H 29/853; H10K 59/1201; H10K 71/851

(57) ABSTRACT

A display device includes a substrate having a display area and a non-display area outside the display area. A trimming portion is formed at an edge of the non-display area, and the trimming portion is configured as a recessed region produced by removing one or more insulating layers. A cover layer is positioned over the entire trimming portion and extends to an outmost side surface of the substrate. The cover layer extends into the recessed trimming portion to stabilize the trimmed edge and to suppress separation or lifting of films at the substrate perimeter. The display device may further include a thin film transistor, a light emitting element, or additional layers formed in the display area. The structure enhances edge reliability while supporting conventional manufacturing and various substrate materials.

### CROSS-REFERENCE TO RELATED APPLICATION

This application claims priority under 35 U.S.C. § 119(a) to the Korean Patent Application No. 10-2024-0200603, filed in the Republic of Korea on Dec. 30, 2024, the entire contents of which are hereby expressly incorporated by reference into the present application.

### BACKGROUND

### Technical Field

The present disclosure relates to a display device, and more particularly to, a display device capable of preventing a film breakaway at an edge thereof.

### Description of the Related Art

As information technologies have advanced over the years, various display devices with small and thin types such as a liquid crystal display device, an organic light-emitting display device, a plasma display device and a micro LED display device have been proposed. Such display devices have been applied to small mobile electronic apparatuses such as a smart phone or a tablet PC.

Those display devices can be manufactured by forming multiple display panels on a mother substrate, and then cutting and trimming the display panels into a unit panel. In addition, in case of manufacturing an unusually shaped display device such as a clock display device or a vehicle display device, the display panels are formed on a rectangular mother substrate, and then cutting and trimming processes are performed to manufacture display devices of the desired shapes.

However, when trimming the mother substrate, the insulating film in the trimmed area can be broken away. This breakaway of the film has become a major cause of separation or cracking of the film.

### BRIEF SUMMARY

The present disclosure relates to a trimming edge structure that suppresses film lifting and polarizer separation, issues that commonly arise when a display panel is cut or trimmed. In conventional approaches, trimming the mother substrate often causes portions of insulating films in the trimmed region to detach or crack, and this detachment can propagate and lead to further separation of adjacent layers. To address this problem, the present disclosure forms the trimming portion as a recessed region and places a cover layer across the entire recessed area, including the outermost side surface of the substrate. By fully covering the recessed portion, the present disclosure avoids exposing interfaces between organic and inorganic films that are prone to separation during mechanical or laser cutting.

The present disclosure further provides a multi layer inorganic buffer structure formed of oxide, nitride and oxide materials. Differences in etching characteristics between these materials allow a portion of the first oxide layer to remain at the bottom of the recessed trimming portion after etching. This remaining layer strengthens adhesion with the cover layer and stabilizes the substrate edge, particularly when the substrate is formed of a polymer material. In addition, the recessed trimming portion is created at the same time as the contact holes through the use of two mask processes, removing the need for a separate trimming mask and thereby reducing processing steps and manufacturing cost.

As a result, the present disclosure provides a continuous laminated arrangement in which the remaining buffer layer and the cover layer act together to reinforce the trimmed edge. This structure enhances mechanical stability, prevents lifting of both the cover layer and the polarizer, and supports reliable performance in displays formed on flexible or non standard substrate shapes.

Accordingly, one or more embodiments of the present disclosure are directed to a display device that substantially obviates one or more of the problems due to the limitations and disadvantages of the related art.

An aspect of the present disclosure is to provide a display device that can be manufactured by simple processes and/or lower production cost.

Another aspect of the present disclosure is to provide a display device capable of preventing breakaway of a cover layer in a trimming portion.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a display device that comprises a substrate including a display area and a non-display area positioned outside of the display area, a light-emitting diode and a thin film transistor disposed on the display area of the substrate, a trimming portion disposed on an edge of the non-display area of the substrate, and a cover layer positioned on the entire trimming portion and extending to an outmost side surface of the substrate.

A buffer layer comprising a first buffer layer of a first inorganic material, a second buffer layer of a second inorganic material disposed on the first buffer layer and a third buffer layer of a third inorganic material disposed on the second buffer layer is disposed on the substrate.

In one embodiment, at least a portion of the first buffer layer is positioned on a bottom of the trimming portion and/or the buffer layer is in contact with the cover layer.

In another embodiment, the display device further comprises a planarization layer covering the thin film transistor and the planarization layer can comprise a same material as the cover layer.

In one or more embodiments, since an additional single mask process is not required compared to conventional display devices, it is possible to manufacture the display device quickly and at low production costs.

Since the cover layer is formed over the entire area on the first buffer layer in the trimming portion, both the first buffer layer and the cover layer can have a robust film structure. The display device is cut and trimmed in a state in which the first buffer layer and the cover layer are laminated. The breakaway or lifting at the edge of the cover layer can be prevented, and as a result, the defect of the polarizer on the cover layer can also be prevented.

In addition, since the breakaway at the edge of the cover layer and/or the defect of the polarizer can be prevented, it is possible to implement an eco-friendly device with minimized use of hazardous substances.

It is to be understood that both the foregoing general description and the following detailed description are examples and explanatory, and are intended to provide further explanation of the inventive concepts as claimed.

### BRIEF DESCRIPTION OF THE SEVERAL VIEWS OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic block diagram of a display device in accordance with one or more embodiments of the present disclosure.

FIG. 2 illustrates a schematic block diagram of a sub-pixel in the display device in accordance with one or more embodiments of the present disclosure.

FIG. 3 illustrates a schematic circuit diagram of a sub-pixel in the display device in accordance with one or more embodiments of the present disclosure.

FIG. 4 illustrates a schematic plane view of a display device in accordance with one or more embodiments of the present disclosure.

FIG. 5 illustrates a schematic cross-sectional view of the display device taken along a line I-I′ of FIG. 4.

FIG. 6 illustrates a schematic display device where a cover layer is formed in a portion of a trimming portion.

FIGS. 7A to 7E illustrates a manufacturing process of the display device in one or more embodiments of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure unless otherwise specified. Further, in the following description of the present disclosure, where a detailed description of a known related art may unnecessarily obscure the gist of the present disclosure, the detailed description thereof may be omitted herein or may be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included

Although the terms first, second, and the like may be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

In describing components of the present disclosure, terms such as first, second, A, B, (a), (b), etc., may be used. These terms are only intended to distinguish the components from other components, and the nature, order, sequence, or numbers of the components are not limited by the terms. When it is described that a component is “connected,” “coupled,” or “connected” to another component, it should be understood that the component may be directly connected or connected to the other component, but that other components may also be “interposed” between each component, or that each component may be “connected,” “coupled,” or “connected” through another component.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

As used herein, ‘display device’ can comprise a narrowly defined display device such as a display module including a display panel and a driving unit for driving the display panel. In addition, the display device can also include a set electronic device or a set apparatus such as a notebook computer, a television, a computer monitor, an automotive display, or other forms of a vehicle display, which are complete products (or final products) including a display module, an equipment display, a mobile electronic device such as a smart phone or an electronic pad, and the like.

Therefore, the display device in the present disclosure can include a narrowly defined display device itself such as a display module, and a set apparatus which is an application product or a final consumer device including a display module.

The present disclosure can be applied to various display devices. For example, the disclosure can be applied to an organic light-emitting display device, a liquid crystal display device, an electrophoretic display device, a quantum-dot display device, a micro light-emitting diode (LED) display device, a mini LED display device. For the convenience of explanation, the organic light-emitting display device as an example of the display device can be described. However, the present disclosure is not limited to the organic light-emitting display device.

Reference will now be made in detail to aspects of the disclosure, examples of which are illustrated in the accompanying drawings. Wherever possible, the same reference numbers will be used throughout the drawings to refer to the same or like parts.

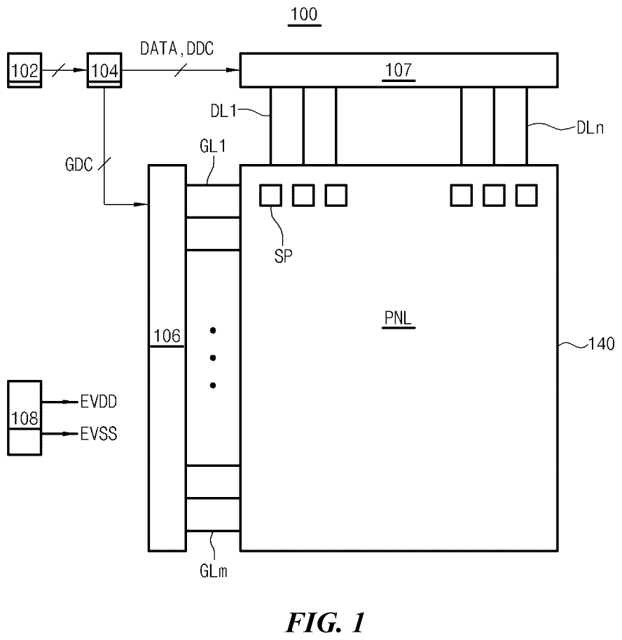

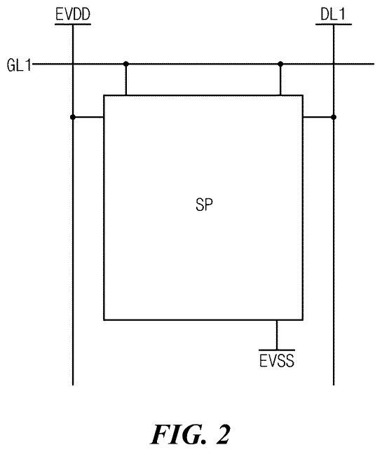

FIG. 1 illustrates a schematic block diagram of a display device in accordance with the present disclosure. FIG. 2 illustrates a schematic block diagram of a sub-pixel in the display device in accordance with the present disclosure.

Referring FIG. 1, a display device 100 can comprise an image processor 102, a timing controller 104, a gate driver 106, a data driver 107, a power supplier 108 and a display panel PNL.

The image processor 102 outputs driving signals for driving various components together with an image data supplied from outside. For example, the driving signal output form the image processor 102 can comprise, but is not limited to, a data enable signal, a vertical synchronization signal, a horizontal synchronization signal, a clock signal, and the like.

The timing controller 104 receives driving signals along with the image data from the image processor 102. The timing controller 104 generates and outputs a gate timing control signal GDC for controlling an operation timing of the gate driver 106 and a data timing control signal DDC for controlling an operation timing of the data driver 107 based on the driving signal input from the image processor 102.

The gate driver 106 outputs a scan signal to the display panel PNL in response of the gate timing control signal GDC supplied from the timing controller 104. The gate driver 106 outputs the scan signal though a plurality of gate lines GL1 to GLm (m is an integer equal to or greater than 2). In one embodiment, the gate driver 106 can be shaped as an integrated circuit (IC), but is not limited thereto. The gate driver 106 can be positioned directly on a substrate 140 of the display panel PNL. In this case, the gate driver 106 can be a GIP (Gate-In-Panel).

The data driver 107 outputs data voltage to the display panel PNL in response of the data timing control signal DDC input from the timing controller 104. The data driver 107 samples and latches a digital-type data signal DATA supplied from the timing controller 104 and convers the digital-type data signal DATA into analog-type data voltage based on a gamma voltage. The data driver 107 outputs the data voltage through a plurality of data lines DL1 to DLn (n is an integer equal to or greater than 2). In one embodiment, the data driver 107 can be shaped as an integrated circuit (IC), but is not limited thereto.

The power supplier 108 outputs high-potential voltage VDD and low-potential voltage VSS and supplies the voltages VDD and VSS to the display panel PNL. The high-potential voltage VDD is supplied to the display panel PNL through a first power line EVDD and the low-potential voltage VSS is supplied to the display panel PNL through a second power line EVSS. Alternatively or additionally, the voltages output from the power supplier 108 can be output to the gate driver 106 and/or the data driver 107 for driving the gate driver 106 and/or the data driver 107.

The display panel PNL display images in response to the scan signal supplied from the gate driver 106, the data voltage supplied from the data driver 107 and the power supplied from the power supplier 108.

The display panel PNL comprises a plurality of sub-pixels SPs to display an image. In one embodiment, the sub-pixel SP can comprise a red (R) sub-pixel, a green (G) sub-pixel and a blue (B) sub-pixel. Alternatively, the sub-pixel SP can comprise a white (W) sub-pixel, a red (R) sub-pixel, a green (G) sub-pixel and a blue (B) sub-pixel. In one embodiment, the white (W), red (R), green (G) and blue (B) sub-pixels can have a substantially same area. Alternatively, the white (W), red (R), green (G) and blue (B) sub-pixels can have different areas.

Referring to FIG. 2, each sup-pixel SP can be connected to a gate line GL1, a data line DL1, a first power line EVDD and a second power line EVSS. The sub-pixel SP can comprise a plurality of thin film transistors and a plurality of capacitors by configuration of the pixel circuit in the sub-pixel SP. For example, the sub-pixel SP can consist of two thin film transistors and one capacitor (2T1C), but is not limited thereto. In another embodiment, the sub-pixel can be implemented by 3T1C, 4T1C, 5T1C, 6T1C, 7T1c, 3T2C, 4T2C, 5T2C, 6T2C, 7T2C, 8T2C, and the likes.

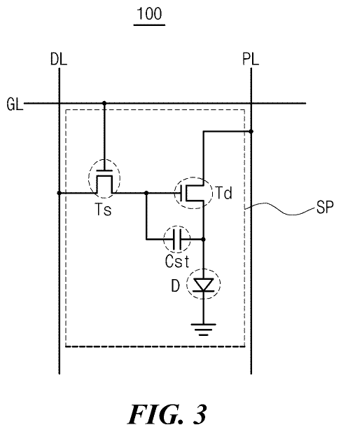

FIG. 3 illustrates a schematic circuit diagram of a sub-pixel in the display device in accordance with the present disclosure.

Referring to FIG. 3, the display device 100 includes a gate line GL, a data line DL and a power line PL crossing each other to define the sub-pixel SP. A switching thin film transistor Ts, a driving thin film transistor Td, a storage capacitor Cst and a light-emitting diode D can be disposed in the sub-pixel SP.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

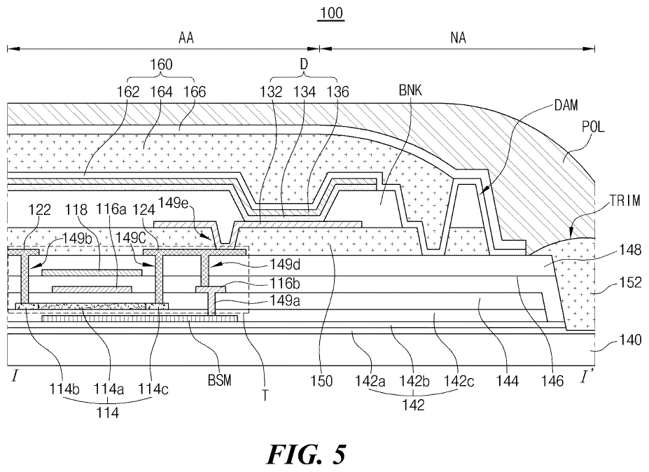

In the display device 100, when the switching thin film transistor Ts is turned on by a gate signal applied to the gate line GL, a data signal applied to the data line DL is applied a gate electrode 116a (FIG. 5) and one electrode of the storage capacitor Cst through the switching thin film transistor Ts.

The driving thin film transistor Td is turned on by the data signal applied to the gate electrode 116a so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 116a in the driving thin film transistor Td is kept constant during one frame. Therefore, the display device 100 can display a desired image.

In FIG. 3, the display device 100 includes two thin film transistors Ts and Td and one storage capacitor Cst in the sub-pixel SP. However, the display device 100 can comprise three or more thin film transistors and two or more storage capacitors.

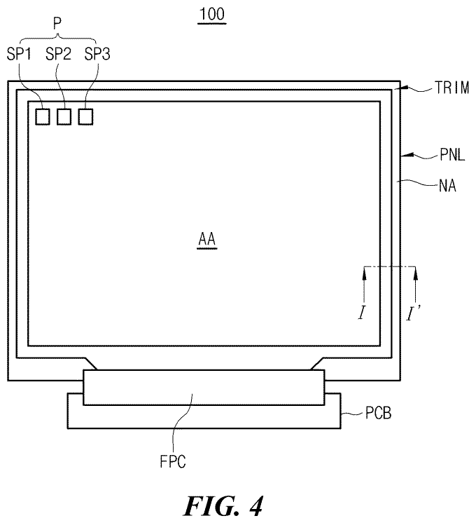

FIG. 4 illustrates a schematic plane view of a display device in accordance with one or more embodiments of the present disclosure.

Referring to FIG. 4, the display device 100 comprises a display panel PNL, a flexible circuit board FPC and a printed circuit board PCB. The display panel PNL comprises a display area AA where an image is displayed and a non-display area NA positioned outsides of the display area AA.

A Pixel P including a plurality of sub-pixels SP1, SP2 and SP3 is arranged in the display area AA. In one embodiment, the sub-pixels SP1, SP2 and SP3 can comprise a red (R) sub-pixel, a green (G) sub-pixel and a blue (B) sub-pixel, respectively. In another embodiment, the pixel P can further comprise a white (W) sub-pixel.

A plurality of gate lines GL1 to GLm (FIG. 1) and a plurality of data lines DL1 to DLn (FIG. 1) can be positioned in the display area AA, and the sub-pixels SP1, SP2 and SP3 can be arranged on an area where the gate line GL1 (FIG. 2) and the data line DL1 (FIG. 2) cross. A switching thin film transistor Ts (FIG. 3) or a driving thin film transistor Td (FIG. 3), and a display element for implementing a real image can be disposed in each of the sub-pixels SP1, SP2 and SP3.

The display element can include various display elements. For example, the display element D can comprise, but is not limited to, an organic light-emitting display diode, a liquid crystal display device, a quantum-dot display diode, a micro LED display diode and a mini LED display diode.

The gate driver 106 (FIG. 1) and the data driver 107 (FIG. 1) supplies various signals to the sub-pixels SP1, SP2 and SP3 can be arranged in the non-display area NA. The gate driver 106 applies the scan signal to the sub-pixels SP1, SP2 and SP3 through the gate lines GL1 to GLm (FIG. 1) and the data driver 107 applies the image signal to the sup-pixels SP1, SP2 and SP3 through the data lines DL1 to DLn. In one embodiment, the gate driver 106 may be a GIP (Gate In Panel) circuit in which a driving circuit is directly integrated on the substrate, but is not limited thereto.

One end of a flexible circuit board FPC is attached to an end of the non-display area NA below the display area AA, and the other end of the flexible circuit board FPC is attached to a printed circuit board PCB. The data driver 107 and a plurality of signal lines are arranged on the flexible circuit board FPC, and the timing controller 104 and the power supplier 108 are arranged on the printed circuit board PCB. The data driver 107 can be mounted directly on the display panel PNL.

The control signals and voltages supplied from the timing controller 104 and the power supplier 108 arranged on the printed circuit board PCB can be applied to the gate driver 106 and the data driver 107 through the signal lines.

A trimming portion TRIM is positioned at an outer edge of the non-display area NA of the display panel PNL. The trimming portion TRIM is an area where the mother substrate on which multiple display panels PNL are formed is cut or separated into display panel PNL units when manufacturing the display device 100, or where trimming process is performed when manufacturing a display device with a different shape. The trimming portion TRIM can be formed by removing multiple insulating layers formed or disposed in the display panel PNL, as will be described below.

FIG. 5 illustrates a schematic cross-sectional view of the display device taken along a line I-I′ of FIG. 4. In FIG. 5, one sub-pixel in the display area AA and the non-display area NA are shown for the convenience of explanation.

Referring to FIG. 5, a substrate 140 includes the display area AA and the non-display area NA. In one embodiment, the substrate 140 can comprise a hard material such as glass and/or a plastic-containing flexible material. For example, when the substrate 140 comprises the plastic-containing material, the substrate 140 can comprise, but is not limited to, polyimide (PI), polymethyl methacrylate (PMMA), polyethylene terephthalate (PET), polyether sulfone (PES), polycarbonate (PC) and combinations thereof.

As an example, when the substrate 140 comprises polyimide, the substrate 140 can comprise multiple polyimide-containing layers. In this case, at least one inorganic layer are interposed between the polyimide-containing layers, but is not limited thereto.

A buffer layer 142 can be disposed on the substrate 140. The buffer layer 142 can be disposed on the entire substrate 140 to improve adhesion between layers disposed on the substrate 140 and the substrate 140, and to block alkaline components, etc., from leaking out from the substrate 140. In addition, the buffer layer 142 can delay the diffusion of moisture or oxygen that has penetrated into the substrate 140.

In one embodiment, the buffer layer 142 can comprise a first buffer layer 142a disposed on the substrate 140, a second buffer layer 142b disposed on the first buffer layer 142a and a third buffer layer 142c disposed on the second buffer layer 142b. The first buffer layer 142a can comprise a first inorganic material, the second buffer layer 142b can comprise a second inorganic material and the third buffer layer 142c can comprise a third inorganic material.

In one exemplary embodiment, the first inorganic material can comprise a first inorganic oxide, the second inorganic material can comprise an inorganic nitride, and the third inorganic material can comprise a second inorganic oxide. For example, the first inorganic material of the first buffer layer 142a and the third inorganic material of the third buffer layer 142c can comprise silicon oxide (SiOₓ, wherein 0<x≤2), respectively, and the second inorganic material of the second buffer layer 142b can comprise silicon nitride (SiNₓ, wherein 0<x≤2), but is not limited thereto.

A bottom shield metal BSM is disposed on the second buffer layer 142b in the display area AA. The bottom shield metal BSM can be arranged to minimize the back channel phenomenon caused by charges trapped in the substrate 140 and to prevent afterimages or performance degradation of the thin film transistor T. For example, the bottom shield metal BSM can comprise, but is not limited to, a metal component.

The thin film transistor T is arranged on the third buffer layer 142c in the display area AA. For the convenience of explanation, only the driving thin film transistor among the various thin film transistors that can be arranged in the display area AA is illustrated in FIG. 5, but other thin film transistor such as a switching thin film transistor may be disposed. In addition, the thin film transistor with a top gate structure is illustrated in FIG. 5, the structure of the thin film transistor T is not limited thereto, and the thin film transistor T with other structures such as a bottom gate structure can be implemented.

The thin film transistor T can comprise a semiconductor layer 114, a gate electrode 116a, a source electrode 122 and a drain electrode 124.

The semiconductor layer 114 is disposed on the buffer layer 142 and a gate insulating layer 144 is disposed on the semiconductor layer 114.

In one embodiment, the semiconductor layer 114 can comprise a polycrystalline semiconductor. For example, the polycrystalline semiconductor can comprise, but is not limited to, low temperature poly silicon (LTPS) with beneficial mobility.

In another embodiment, the semiconductor layer 114 can comprise an oxide semiconductor. For example, the oxide semiconductor can comprise, but is not limited to, indium-gallium-zinc oxide (IGZO), indium-zinc oxide (IZO), indium-gallium-tin oxide (IGTO), indium-gallium oxide (IGO) and combinations thereof. In some embodiments, the semiconductor layer 114 can comprise a channel area 114a of the central area, and a source area 114b and a drain area 114c as the doping areas on both sides of the channel areal 114a.

For example, the gate insulating layer 144 can comprise an inorganic insulating material such as silicon oxide (SiOₓ, wherein 0<x≤2) and silicon nitride (SiNₓ, wherein 0<x≤2). The gate insulating layer 144 can have a single-layer structure or a multiple-layer structure. But embodiments of the present disclosure are not limited thereto.

The gate electrode 116a is disposed on the gate insulating layer 144. A connection electrode 116b can be disposed on the gate insulating layer 144. An interlayer insulating layer 146 is disposed on the gate electrode 116a and the connection electrode 116b. In one embodiment, the gate electrode 116a and the connection electrode 116b can be arranged using a same metal component by a same process. In another embodiment, the gate electrode 116a and the connection electrode 116b can be arranged using different metal components in different processes.

The gate electrode 116a and the connection electrode 116b can comprise the metal component. For example, the gate electrode 116a and the connection electrode 116b can comprise, but is not limited to, molybdenum (Mo), aluminum (Al), chrome (Cr), gold (Au), titanium (Ti), nickel (Ni), neodymium (Nd), copper (Cu), combinations thereof, or alloys thereof. The gate electrode 116a and the connection electrode 116b can have a single-layer structure or a multi-layer structure.

In one embodiment, the interlayer insulation layer 146 can comprise, but is not limited to, an organic material such as photo-acryl or an inorganic insulating material such as silicon oxide (SiOₓ, wherein 0<x≤2) and silicon nitride (SiNₓ, wherein 0<x≤2). The interlayer insulating layer 146 can have a single-layer structure or a multiple-layer structure. In another embodiment, the interlayer insulating layer 146 can have a multi-layer structure with at least one organic layer and at least one inorganic layer. But embodiments of the present disclosure are not limited thereto.

The connection electrode 116b can be electrically connected to the bottom shield metal BSM through a first contact hole 149a formed in the buffer layer 142 and the gate insulating layer 144.

A storage electrode 118 is disposed on the interlayer insulating layer 146 in the display area AA. In one embodiment, the storage electrode 118 can comprise, but is not limited to, a metal component. The storage electrode 118 and the gate electrode 116a can form the storage capacitor Cst (FIG. 3).

A passivation layer 148 is disposed on the interlayer insulating layer 146 on which the storage electrode 118 is disposed, and the source electrode 122 and the drain electrode 124 are disposed on the passivation layer 148 in the display area AA.

In one embodiment, the passivation layer 148 can comprise an organic material such as photo-acryl. In another embodiment, the passivation layer 148 can comprise an inorganic material such as silicon oxide (SiOₓ, wherein 0<x≤2) and silicon nitride (SiNₓ, wherein 0<x≤2). In another embodiment, the passivation layer 148 can comprise multiple layers with at least one inorganic layer and at least one organic layer.

In an embodiment, each of the source electrode 122 and the drain electrode 124 can comprise, but is not limited to, molybdenum (Mo), aluminum (Al), chrome (Cr), gold (Au), titanium (Ti), nickel (Ni), neodymium (Nd), copper (Cu), combinations thereof, or alloys thereof. Each of the source electrode 122 and the drain electrode 124 can have a single-layer structure or a multi-layer structure. But embodiments of the present disclosure are not limited thereto. The source electrode 122 and the drain electrode 124 can be contacted to the source area 114b and the drain area 114c of the semiconductor layer 114, respectively, through a second contact hole 149b and a third contact hole 149c formed in the gate insulating layer 144, the interlayer insulating layer 146 and the passivation layer 148. The drain electrode 124 can be electrically connected to the connection electrode 116b through a fourth contact hole 149d.

A planarization layer 150 can be disposed on the substrate 140 over which the thin film transistor T is disposed. In one embodiment, the planarization layer 150 can comprise, but is not limited to, an organic material such as photo-acryl. In another embodiment, the planarization layer 150 can comprise an inorganic material such as silicon oxide (SiOₓ, wherein 0<x≤2) and silicon nitride (SiNₓ, wherein 0<x≤2). In another embodiment, the planarization layer 150 can have a multi-layer structure with at least one inorganic layer and at least one organic layer. The planarization layer 150 can comprise a same material as the passivation layer 148 or comprise a material different from the passivation layer 148.

A light-emitting diode D is disposed on the planarization layer 150 in the display area AA. The light-emitting diode D can comprise a first electrode 132, an emissive layer 134 and a second electrode 136 each of which disposed sequentially on the planarization layer 150.

The first electrode 132 is disposed on the planarization layer 150. The first electrode 132 can be electrically connected to the drain electrode 124 of the thin film transistor T through a fifth contact hole 149e formed in the planarization layer 150.

For example, the first electrode 132 can comprise, but is not limited to, a metal component such as silver (Ag), aluminum (Al), gold (Au), molybdenum (Mo), tungsten (W), chrome (Cr), combinations thereof or alloys thereof. In another embodiment, the first electrode 132 can comprise, but is not limited to, transparent metal oxide layer such as indium-tin oxide (ITO) and/or indium-zinc oxide (IZO).

In one embodiment, when the display device 100 is a top-emission type, the first electrode 132 can further comprise an opaque conductive material acting as a reflection electrode. In another embodiment, when the display device 100 is a bottom-emission type, the first electrode 132 can be disposed using the transparent conductive material such as ITO and/or IZO.

A bank layer BNK is disposed on the planarization layer 150 at the boundary of each sub-pixel. The bank layer BNK can be a kind of a partitioned wall defining each sub-pixel. The bank layer BNK partitions each sub-pixel and can prevent light of a specific color output from adjacent sub-pixels from being mixed and output.

For example, the bank layer BNK can comprise, but is not limited to, an inorganic material such as silicon oxide (SiOₓ, wherein 0<x≤2) and silicon nitride (SiNₓ, wherein 0<x≤2), an organic material such as benzocyclobutene (BCB), an acryl-containing resin, an epoxy-containing resin, a phenol-containing resin, a polyamide-containing resins and/or a polyimide-containing resin, and a photo-sensitive agent containing a black pigment and/or dye, and combinations thereof.

The emissive layer 134 can be arranged on the first electrode 132. In one embodiment, the emissive layer 134 can comprise, but is not limited to, a red emissive layer emitting red color and disposed in the red sub-pixel, a green emissive layer emitting green color and disposed in the green sub-pixel and a blue emissive layer emitting blue color and disposed in the blue sub-pixel. For example, the emissive layer 134 can comprise, but is not limited to, an organic emissive layer, or an inorganic emissive layer such as a nano-sized material layer, quantum dots, a micro LED emissive layer or a mini LED emissive layer.

In one embodiment, the emissive layer 134 can comprise an emitting material layer. In another embodiment, the emissive layer 134 can further comprise a hole injection layer, a hole transport layer, and/or an electron blocking layer disposed between the first electrode 132 and the emitting material layer, and an electron injection layer, an electron transport layer and/or a hole blocking layer disposed between the emitting material layer and the second electrode 136.

The second electrode 136 is disposed on the emissive layer 134. In one embodiment, the second electrode 136 can have a single-layer structure or a multi-layer structure with a metal component or alloys thereof. In another embodiment, the second electrode 136 can comprise a transparent metal oxide such as ITO and/or IZO. But the embodiments of the present disclosure are not limited thereto.

In one embodiment, when the display device 100 is a top-emission type, the second electrode 136 can be arranged using the transparent or semi-transparent conductive material. For example, the second electrode 136 can comprise, but is not limited to, an alloy such as LiF/Al, CsF/Al, Mg:Ag, Ca/Ag, Ca:Ag, LiF/Mg:Ag, LiF/Ca/Ag, LiF/Ca:Ag and combinations thereof.

In another embodiment, when the display device 100 is a bottom-emission type, the second electrode 136 can be arranged using an opaque conductive material. For example, the second electrode 136 can comprise, but is not limited to, silver (Ag), aluminum (Al), gold (Au), molybdenum (Mo), tungsten (W), chrome (Cr) and/or alloys thereof.

In another embodiment, the light-emitting diode D can have a tandem structure. The tandem structure includes a plurality of emitting parts and at least one charge generation layer disposed between the emitting parts. The charge generation layer is intended to connecting the plural emitting parts. In one embodiment, a plurality of charge generation layers including a first charge generation layer and a second charge generation layer can be disposed. In one embodiment, the charge generation layer can include an N-type charge generation layer and a P-type charge generation layer. For example, the charge generation layer can comprise, but is not limited to, an organic layer doped with alkali metal such as Li, Na, K and/or Cs and/or alkaline earth metal such as Mg, Sr, Ba and/or Ra.

An encapsulation layer 160 is disposed in the display area AA and the non-display area NA to encapsulate the light-emitting diode D. When the light-emitting diode D is exposed to moisture or oxygen, a pixel shrinkage phenomenon in which the light emission area shrinks or a defect in which a dark spot is formed within the light emission area may occur. In addition, the moisture or oxygen may oxidize the electrode made of the metallic component. The encapsulation layer 160 blocks the penetration of moisture and oxygen from the outside to prevent defects in the light-emitting diode D and various electrodes.

In one embodiment, the encapsulation layer 160 can comprise, but is not limited to, a first encapsulation layer 162, a second encapsulation layer 164 and a third encapsulation layer 166. In another embodiment, the encapsulation layer 160 can comprise two layers or four or more layers.

In one embodiment, each of the first encapsulation layer 162 and the third encapsulation layer 164 can comprise an inorganic material such as silicon oxide (SiOₓ, wherein 0<x≤2) and silicon nitride (SiNₓ, wherein 0<x≤2). Each of the first encapsulation layer 162 and the third encapsulation layer 164 can have a single-layer structure or a multi-layer structure. In another embodiment, each of the first encapsulation layer 162 and the third encapsulation layer 164 can further comprise at least one organic layer disposed between the inorganic layers. The second encapsulation layer 164 can comprise an epoxy-containing resin. But the embodiments of the present disclosure are not limited thereto.

While not shown in FIG. 5, a touch member can be disposed on the encapsulation layer 160. The touch member can be disposed in the display area AA and sense the touch input. The touch member can sense outer touch information using user's finger or a touch pen.

A dam component DAM is arranged in the non-display area NA. Since the organic material in the second encapsulation layer 164 has fluidity, the organic material may flow out to the outside of the substrate 140 through the outside of the non-display area NA due to the fluidity when the second encapsulation layer 164 is formed. The dam component DAM is formed to surround the display area AA to trap the organic material flowing out of the substrate 140 when the second encapsulation layer 164 is formed, and thereby preventing the organic material from flowing out of the substrate 140. Although one dam component DAM is illustrated in FIG. 5, a plurality of dam components DAMs can be disposed in the non-display area NA.

In one embodiment, the dam component DAM can have a multi-layer structure. For example, the dam component DAM can be formed of a layer of a same material as the planarization layer 150 and the bank layer BNK. However, the dame component DAM of the present disclosure is not limited thereto, but can have a triple-layer structure or a single-layer structure.

The trimming portion TRIM is positioned at an edge of the display device 100. In one embodiment, the trimming portion TRIM can be formed by removing the passivation layer 148, the interlayer insulating layer 146, the gate insulating layer 144, the second buffer layer 142b and the third buffer layer 142c.

A cover layer 152 is disposed on a bottom surface of the trimming portion TRIM to fill the inside of the trimming portion TRIM. To further elaborate, when the inside of the trimming portion TRIM is filled with the cover layer 152, this does not imply a narrow interpretation of the trimming portion TRIM being “filled” exclusively with the cover layer 152 to the exclusion of other materials. Namely, the term “filled with,” as used herein, is intended to encompass a broad range of conditions, including but not limited to “partially filled with,” “substantially filled with,” “completely filled with,” or “exclusively filled with.”

A polarizer POL is disposed in the display area AA and the non-display area NA. The polarizer POL is formed on a light output side of the display device 100, that is, on a display area on which the image is displayed, to prevent light incident from the outside from being reflected.

The polarizer POL can comprise a polyvinyl alcohol-containing polarizing layer in which at least one of iodine and dichroic dye is oriented in a predetermined direction. In one embodiment, the polarizer POL can be a polyvinyl alcohol-containing polarizing layer in which iodine and/or the dichroic dye are oriented in a predetermined direction. In another embodiment, the polarizer POL can be a film laminator in which a transparent polymer film is attached to one surface of the polyvinyl alcohol-containing polarizing layer. In some embodiments, the polarizer can be omitted in accordance with the structure of the display device 100.

The trimming portion TRIM can be formed by removing the passivation layer 148, the interlayer insulating layer 146, the gate insulating layer 144, the second buffer layer 142b and the third buffer layer 142c, and at least a portion of the first buffer layer 142a exists on the bottom surface of the trimming portion TRIM. While the first buffer layer 142a with a partial thickness is formed on the bottom surface of the trimming portion TRIM, but the first buffer layer 142a with a total thickness can be formed on the bottom surface of the trimming portion TRIM.

The cover layer 152 can be positioned over the entire trimming portion TRIM. Since the trimming portion TRIM is an area in which the display device 100 is cut and trimmed, the edge of the trimming portion TRIM becomes the outmost side surface of the display device 100. In one embodiment, since the cover layer 152 extends to the outmost side surface of the display device 100, the cover layer 152 is exposed to the outside through the outmost side surface of the display device 100. In one embodiment, the cover layer 152 can comprise a same material as the planarization layer 150, but is not limited thereto. As described above, since the cover layer 152 is formed or positioned on the entire trimming portion TRIM, lifting or breakaway of the cover layer 152 and adhesion failure or defect of the polarizer POL on the cover layer 152 can be prevented, which will be described in more detail below.

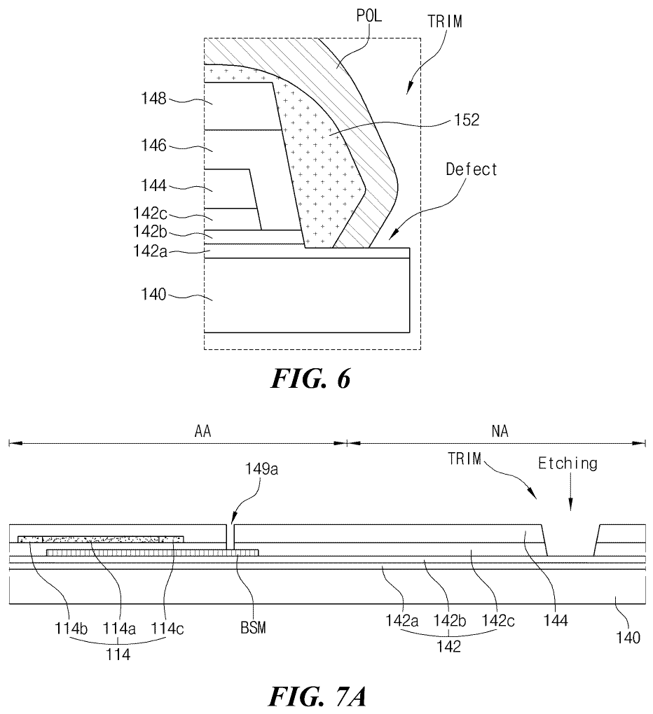

FIG. 6 illustrates a schematic display device where a cover layer is formed in a portion of a trimming portion.

Referring to FIG. 6, since the first buffer layer 142a comprises the inorganic material and the cover layer 152 of an organic material is disposed on the first buffer layer 142a in the display device, the cover layer 152 may be lifted or broken away from the first buffer layer 142a in trimming the display device due to a weak adhesive force at an interface between the inorganic material of the first buffer layer 142a and the organic material of the cover layer 152. In particular, the cover layer 152 is formed only on a partial area of the first buffer layer 142a, lifting or breakaway frequently occurs at the edge of the cover layer 152 on the first buffer layer 142a.

The lifting or breakaway of the cover layer 152 causes adhesion failure in the trimming portion TRIM when the polarizer POL is attached to the cover layer 152. As the unattached area of the non-display area NA propagates to the display area AA, there was also a problem in that the polarizer POL of the display area AA was lifted from the cover layer 152 so that external light is reflected to the outside of the display device 100 or even the polarizer POL was broken away from the display device 100. In particular, as the adhesion defect of the polarizer POL occurs at the edge of the cover layer 152, this adhesion defect propagates inside, causing an adhesion defect in the entire polarizer POL.

On the other hand, since the cover layer 152 is formed over the entire area on the first buffer layer 142a in the trimming portion TRIM in accordance with an embodiment of the present disclosure, the film structure of the first buffer layer 142a and the cover layer 152 becomes robust. In addition, the display device 100 is cut and trimmed in a state in which the first buffer layer 142a and the cover layer 152 are laminated, a lifting or breakaway at the edge of the cover layer 152 can be prevented, and a s a result, the adhesion defect of the polarizer POL disposed on the cover layer 152 can also be prevented.

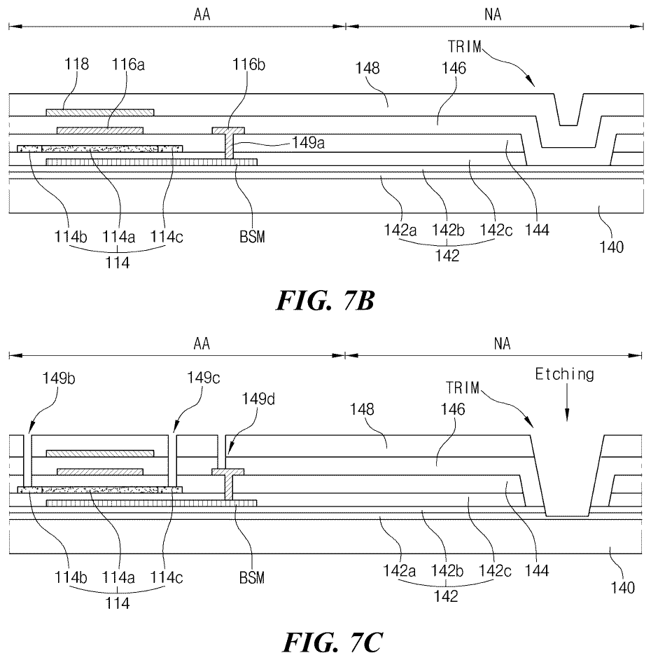

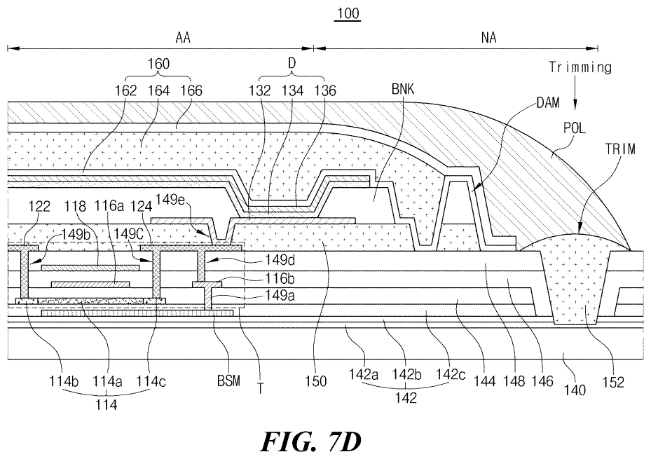

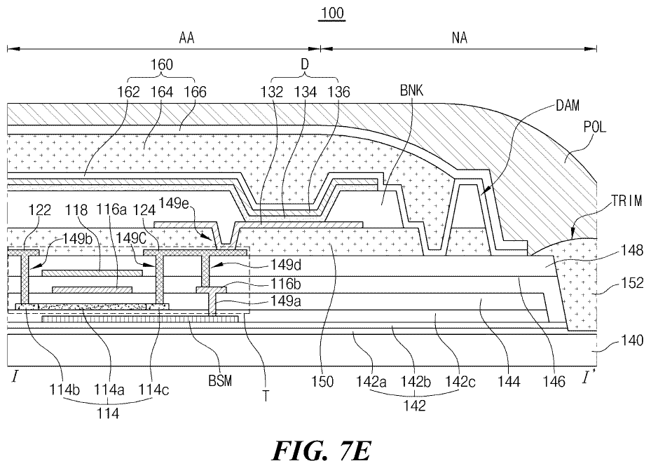

FIGS. 7A to 7E illustrates a manufacturing process of the display device in one or more embodiments of the present disclosure.

Referring to FIG. 7A, the buffer layer 142 is disposed on the entire surface of the substrate 140 including the display area AA and the non-display area NA. The substrate 140 can comprise a hard material such as glass and/or a flexible plastic-containing material such as polyimide (PI), polymethyl methacrylate (PMMA), polyethylene terephthalate (PET), polyether sulfone (PES), polycarbonate (PC) and combinations thereof.

For example, the buffer layer 142 can be formed, but is not limited to, by disposing the first buffer layer 142a of silicon oxide (SiOₓ, wherein 0<x≤2), the second buffer layer 142b of silicon nitride (SiNₓ, wherein 0<x≤2) and the third buffer layer 142c of silicon oxide (SiOₓ, wherein 0<x≤2). The bottom shield metal BSM is formed in the display area AA by laminating metal on the second buffer layer 142b and etching the metal.

The semiconductor layer 114 is disposed in the display area AA by laminating a polycrystalline semiconductor such as polysilicon or an oxide semiconductor such as indium-gallium-zinc oxide (IGZO), indium-zinc oxide (IZO), indium-gallium-tin oxide (IGTO), and/or indium-gallium oxide (IGO) on the buffer layer 142 and etching the semiconductor. In addition, the channel area 114a, the source area 114b and the drain area 114c are formed by doping impurities on both sides of the semiconductor layer 114.

The gate insulating layer 144 is disposed in the display area AA and the non-display area NA by laminating the inorganic material such as silicon oxide (SiOₓ, wherein 0<x≤2) and silicon nitride (SiNₓ, wherein 0<x≤2) on the buffer layer 142 and the semiconductor layer 114.

The first contact hole 149a on the bottom shield metal BSM in the display area AA and the trimming portion TRIM in the non-display area NA are formed by etching the third buffer layer 142c and the gate insulating layer 144 using an etching gas.

Referring to FIG. 7B, the gate electrode 116a and the connection electrode 116b are formed on the gate insulating layer 144 in the display area AA by laminating metal such as molybdenum (Mo), aluminum (Al), chrome (Cr), gold (Au), titanium (Ti), nickel (Ni), neodymium (Nd), copper (Cu), combinations thereof, or alloys thereof over the entire substrate 140 using a sputtering method. In this case, the connection electrode 116b is electrically connected to the bottom shield metal BSM through the first contact hole 149a formed in the gate insulating layer 144.

The interlayer insulating layer 146 is disposed on the entire substrate 140, and the storage electrode 118 is formed in the display area AA by laminating and etching a metal layer. Then, the passivation layer 148 is disposed on the entire substrate 140.

Referring to FIG. 7C, the second contact hole 149b and the third contact hole 149c are formed by etching the gate insulating layer 144, the interlayer insulating layer 146 and the passivation layer 148 on the source area 114b and the drain area 114c, and the fourth contact hole 149d is formed by etching the interlayer insulating layer 146 and the passivation layer 148 on the connection electrode 116b.

At the same time, the interlayer insulating layer 146, the passivation layer 148 and the second buffer layer 142b laminated in the trimming portion TRIM in the non-display area NA are etched. In this case, the first buffer layer 142a remains on the bottom surface of the trimming portion TRIM. In another embodiment, a portion of the first buffer layer 142a can be etched so that a portion of the first buffer layer 142a can remain on the bottom surface of the trimming portion TRIM.

As such, the reasons that the whole or a part of the first buffer layer 142a remains in the trimming portion TRIM during the etching is described. The first buffer layer 142a and the third buffer layer 142c comprise silicon oxide (SiOₓ, wherein 0<x≤2) and the second buffer layer 142bcomprises silicon nitride (SiNₓ, wherein 0<x≤2). The etching rate of silicon nitride is less than the etching rate of silicon oxide. When the second contact hole 149b, the third contact hole 149c and the fourth contact hole 149d are etched, the etching rate decrease in the second buffer layer 149b, and only a portion of the first buffer layer 149a is etched to remain in the trimming portion TRIM.

Meanwhile, the etching of the trimming portion TRIM is performed simultaneously with the etching of the first contact hole 149a, the second contact hole 149b, the third contact hole 149c and the fourth contact hole 149d in the present disclosure. In other words, the first contact hole 149a, the second contact hole 149b, the third contact hole 149c, the fourth contact hole 149d and the trimming portion TRIM can be formed by two mask processes in the present disclosure.

In the conventional display device, the second contact hole 149b, the third contact hole 149c and the fourth contact hole 149d are etched, and then the trimming portion TRIM is formed by a separate or an additional etching process. In this case, the first contact hole 149a, the second contact hole 149b, the third contact hole 149c, the fourth contact hole 149d and the trimming portion TRIM are formed by three mask processes.

Therefore, the present disclosure does not require an additional mask process compared to the conventional display device, so that the display device 100 can be manufacture quickly with reduced manufacturing costs.

When the first contact hole 149a, the second contact hole 149b, the third contact hole 149c, the fourth contact hole 149d and the trimming portion TRIM are formed by thee mask processes, the first buffer layer 142a does not remain on the bottom surface of the trimming portion TRIM. On the contrary, when the first contact hole 149a, the second contact hole 149b, the third contact hole 149c, the fourth contact hole 149d and the trimming portion TRIM are formed by two mask processes, at least a portion of the first buffer layer 142a remains on the bottom surface of the trimming portion TRIM.

Referring to FIG. 7D, the source electrode 122 in contact with the source area 114b of the semiconductor layer 114 through the second contact hole 149b and the drain electrode 124 in contact with the drain area 114c of the semiconductor layer 114 through the third contact hole 149c are formed by laminating metal component such as Cr, Mo, Ta, Cu, Ti, Al and/or alloys thereof on the passivation layer 148 using a sputtering method and etching the metal so that the thin film transistor T can be fabricated.

The planarization layer 150 in the display area AA and the cover layer 152 in the trimming portion TRIM in the non-display area are formed by laminating the organic material such as photo-acryl or inorganic material such as silicon oxide (SiOₓ, wherein 0<x≤2) and silicon nitride (SiNₓ, wherein 0<x≤2) on the thin film transistor T and the trimming portion TRIM, respectively. In another embodiment, the planarization layer 150 and the cover layer 152 can be formed by different processes. In one embodiment, the cover layer 152 can be formed on the entire trimming portion TRIM to cover the entire trimming portion TRIM.

The first electrode 132 is disposed on the planarization layer 150 by laminating metal component such as silver (Ag), aluminum (Al), gold (Au), molybdenum (Mo), tungsten (W) and chrome (Cr) and etching the metal component. The first electrode 132 is electrically connected to the drain electrode 124 of the thin film transistor T through the fifth contact hole 149e formed in the planarization layer 150.

The bank layer BNK is disposed on the planarization layer 150 by laminating at least one of the inorganic insulating material such as silicon oxide (SiOₓ, wherein 0<x≤2) and silicon nitride (SiNₓ, wherein 0<x≤2), the organic insulating material such as benzocyclobutene (BCB), an acryl-containing resin, an epoxy-containing resin, a phenol-containing resin, a polyamide-containing resins and/or a polyimide-containing resin, and a photo-sensitive agent containing a black pigment and/or dye and a dry etching. The dam component DAM with the same material as the planarization layer 150 and/or the bank layer BNK is formed in the non-display area NA.

The emissive layer 134 is formed by coating or depositing luminous material in the display area AA and the second electrode 136 is formed by laminating metal such as silver (Ag), aluminum (Al), gold (Au), molybdenum (Mo), tungsten (W) and chrome (Cr).

The encapsulation layer 160 encapsulating the display device 100 is formed by forming the first encapsulation layer 162 with the inorganic material, the second encapsulation layer 164 on the first encapsulation layer 162 with the organic material and the third encapsulation layer 166 with the inorganic material.

The polarizer POL is formed by laminating the polarizing material such as polyvinyl alcohol-containing material on the encapsulation layer 160. Then, the display device 100 is fabricated by cutting and trimming the substrate 140 along the trimming portion TRIM as illustrated in FIG. 7E.

The substrate 140 can be cut in various ways. In one embodiment, the substrate 140 can be cut by a mechanical cutting apparatus such as a cutting wheel. In another embodiment, the substrate 140 can be cut by a laser. However, the embodiments of the present disclosure are not limited thereto. When the substrate 140 is cut by a laser cutting device, a carbon dioxide laser may be used, but is not limited thereto.

The trimming of the substrate 140 can also be performed by various methods. In one embodiment, the substrate 140 can be trimmed by a laser. For example, an Ad-Yag laser can be used as the laser, but is not limited thereto. The outer area of the display area AA is removed from the center of the trimming portion TRIM by cutting and trimming to complete the display device 100 having a desired shape.

As described above, the display device 100 can be manufactured by forming the first contact hole 149a, the second contact hole 149b, the third contact hole 149c, the fourth contact hole 149d and the trimming portion TRIM by two mask processes. Therefore, it is possible to simplify the manufacturing process and to reduce the manufacturing cost.

In addition, the cover layer 152 is formed over the entire trimming portion TRIM to cover the first buffer layer 142a inside the trimming portion TRIM, thereby preventing the first buffer layer 142a and the cover layer 152 from being lifted or broken away when the display device 100 is cut and trimmed along the trimming portion TRIM. In other words, the manufacturing process of the display device 100 can be simplified by reducing the mask process, and the manufacturing cost can be reduced while preventing the first buffer layer 142a and the cover layer 152 from being lifted in the present disclosure.

It will be apparent to those skilled in the art that various modifications and variations can be made in the present disclosure without departing from the scope of the disclosure. Thus, it is intended that the present disclosure cover the modifications and variations of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area adjacent to the display area, the substrate having an outermost side surface;
a light-emitting element and a thin film transistor disposed on the display area of the substrate;
a trimming portion disposed on an edge of the non-display area of the substrate; and
a cover layer disposed on an entire trimming portion and extending to the outmost side surface of the substrate.

2. The display device of claim 1, wherein the trimming portion includes a recess portion concaving towards the substrate.

3. The display device of claim 2, wherein the trimming portion is formed by removing a plurality of insulating layers laminated in the non-display area.

4. The display device of claim 2, wherein the cover layer extends into an entire bottom surface of the recess portion.

5. The display device of claim 1, further comprising a buffer layer disposed on the substrate.

6. The display device of claim 5, wherein the buffer layer comprises:
a first buffer layer of a first inorganic material;
a second buffer layer of a second inorganic material disposed on the first buffer layer; and
a third buffer layer of a third inorganic material disposed on the second buffer layer.

7. The display device of claim 6, wherein an etching rate of the second inorganic material is smaller than an etching rate of the first inorganic material.

8. The display device of claim 6, wherein the first inorganic material comprises an inorganic oxide and the second inorganic material comprises an inorganic nitride.

9. The display device of claim 8, wherein the third inorganic material comprises an inorganic oxide.

10. The display device of claim 9, wherein each of the first inorganic material and the third inorganic material comprises silicon oxide (SiOₓ, wherein 0<x≤2).

11. The display device of claim 9, wherein the second inorganic material comprises silicon nitride (SiNₓ, wherein 0<x≤2).

12. The display device of claim 1, wherein the cover layer comprises photo-acryl.

13. The display device of claim 1, wherein the cover layer comprises silicon oxide (SiOₓ, wherein 0<x≤2) or silicon nitride (SiNₓ, wherein 0<x≤2).

14. The display device of claim 6, wherein at least a portion of the first buffer layer is disposed on a bottom of the trimming portion.

15. The display device of claim 14, wherein the first buffer layer is in contact with the cover layer.

16. The display device of claim 1, further comprising a planarization layer covering the thin film transistor.

17. The display device of claim 16, wherein the light-emitting element is disposed on the planarization layer.

18. The display device of claim 16, wherein the planarization layer comprises a same material as the cover layer.

19. The display device of claim 16, wherein the planarization layer comprises photo-acryl.

20. The display device of claim 16, wherein the planarization layer comprises silicon oxide (SiOₓ, wherein 0<x≤2) or silicon nitride (SiNₓ, wherein 0<x≤2).
